(19) United States
(12) Patent Application Publication
(10) Pub. No.: US 2007/0076478 A1
(43) Pub. Date: Apr. 5, 2007

(54) System and method of memory block management

(75) Inventor: Richard Sanders, Hutto, TX (US)

Correspondence Address: TOLER SCHAFFER, LLP, 8500 BLUFFSTONE COVE, SUITE A201, AUSTIN, TX, 78759, US

(73) Assignee: SigmaTel, Inc., Austin, TX (US)

(21) Appl. No.: 11/240,581

(22) Filed: Sep. 30, 2005

(51) Int. Cl. G11C 16/04

(52) U.S. Cl. 365/185.11

(57) ABSTRACT

The disclosure is directed to a method of managing data storage. The method includes detecting an unusable memory block. The unusable memory block is in a set of user accessible memory blocks of a memory device. The memory device includes the set of user accessible memory blocks, a set of defective memory blocks, and a set of replacement memory blocks. The set of user accessible memory blocks includes not more than one half of a total number of memory blocks of the memory device and includes memory blocks from both halves of the memory device as addressed by a significant address bit. The method also includes indicating that the unusable memory block is a defective memory block and includes allocating a replacement memory block from the set of replacement memory blocks to the set of user accessible memory blocks.

### FIELD OF THE DISCLOSURE

This disclosure, in general, relates to systems and methods of memory block management.

### BACKGROUND

Increasingly, consumers are demanding portable electronic devices, such as personal digital assistants (PDAs), MP3 players, portable storage systems, advanced wireless telephones, cameras, and other handheld devices. Traditional non-volatile storage mediums, such as hard drives and floppy drives, are generally unsuitable for portable devices. These typical devices have moving parts and, as such, are subject to mechanical failure. In addition, such devices are bulky and consume a large amount of energy. As a result, manufacturers are turning to solid-state non-volatile memory devices, such as electrically erasable programmable read-only memory (EEPROM) and flash memory, for use in portable products.

As portable electronic devices become more complex, these systems tend to utilize larger memory capacities. However, solid-state memory devices are generally expensive. Typically, the price per unit memory of a solid-state memory device increases with increase in capacity. Often, the price increase results from difficulties in manufacturing larger capacity devices with enough error free blocks to meet manufacture specifications. For example, a manufacturer may specify an end of life capacity of a solid-state memory device, such as a capacity of 97% of the blocks of the solid-state memory device, resulting in the expectation that 3% of the memory device is inoperable at the end of the memory device's useful life. As such, systems utilizing such memory devices typically allocate replacement blocks to allow for continued system operation with little interruption in the event that blocks fail.

For example, a typical 128 device that contains 1024 blocks and has a 3% failure at end of life results in system firmware reserving 31 usable and defective blocks, bringing the accessible media size to about 124 megabytes. When, at the time of manufacture, the memory device has a number of defective blocks exceeding 31, the device is outside manufacturer specifications and may be considered defective.

In some situations, the defective blocks are distributed through both halves of the memory device as addressed by a significant address bit and, as such, each half of the memory space includes enough defective blocks to prevent sale of the memory device. For example, in a typical 128 device having 1024 blocks, 17 defective blocks may reside in a first half and 17 defective blocks may reside in a second half of the memory device, resulting in failure of the device as a whole to meet specifications and failure of each half of the memory space to meet specifications. Such memory devices are typically discarded.

As such, a new system and method for managing memory blocks and a memory device would be desirable.

### BRIEF DESCRIPTION OF THE DRAWINGS

FIGS. and 2 include illustrations of components of exemplary electronic devices for accessing memory.

FIGS. 3 and 4 include illustrations of exemplary memory devices.

FIG. 5 includes an illustration of an exemplary memory controller.

FIGS. 6 and 7 include illustrations of exemplary methods for use with electronic devices, such as the exemplary electronic devices of FIGS. 1 and 2.

### DESCRIPTION OF THE DRAWINGS

In a particular embodiment, the disclosure is directed to a system including a device driver and a memory responsive to the device driver. The device driver is configured to determine the usability of blocks on the memory device and to locate defective memory blocks. In addition, the device driver is configured to allocate a user accessible memory space including usable memory blocks from at least both halves of a memory device as addressed by the most significant address bit. As a result, the memory device includes a set of user accessible memory blocks including memory blocks from both halves of the memory device that are allocated as the user accessible memory space. The memory device further includes a set of defective data blocks and a set of unallocated data blocks. In a further exemplary embodiment, the device driver further allocates a set of system resource blocks not included in the user accessible memory space. In particular embodiments, the device driver and memory device may be included in an embedded system, such as a personal digital assistant (PDA) or MP3 player, or may be included in a portable memory system, such as a thumb drive.

In another particular embodiment, the disclosure is directed to a method of managing data storage. The method includes detecting an unusable memory block. The unusable memory block is in a set of user accessible memory blocks of a memory device. The memory device includes the set of user accessible memory blocks, a set of defective memory blocks, and a set of replacement memory blocks. The set of user accessible memory blocks includes not more than one half of a total number of memory blocks of the memory device and includes memory blocks from both halves of the memory device as addressed by a significant address bit. The method also includes indicating that the unusable memory block is a defective memory block and includes allocating a replacement memory block from the set of replacement memory blocks to the set of user accessible memory blocks.

In another exemplary embodiment, the disclosure is directed to a method of managing data storage. The method includes identifying a set of unusable memory blocks of a memory device and allocating a user accessible memory space including memory blocks from at least two halves of an addressable memory space as indicated by a significant address bit. The user accessible memory space includes not more than half of a total number of memory blocks of the memory device. The memory device includes the set of unusable memory blocks, the user accessible memory space, and a set of unallocated memory blocks.

In a further exemplary embodiment, the disclosure is directed to a controller including logic to identify a user accessible memory space, a list of unusable memory blocks, and a block manager configured to access a memory device to allocate the user accessible memory space. The user accessible memory space includes memory blocks from at least two halves of an addressable memory space of the memory device based on a significant address bit and includes not more than half of the total number of memory blocks of the memory device.

In addition, the disclosure is directed to a device including a memory device controller, and a memory device responsive to the controller. The memory device includes a user accessible memory space, a set of defective memory blocks, and a set of unallocated memory blocks. The user accessible memory space includes memory blocks from at least two halves of the addressable memory space of the memory device based on a significant address bit. The user addressable memory space includes not more than half of a total number of memory blocks of the memory device.

In an exemplary embodiment, FIG. 1 illustrates a memory system 100 including a controller 104 and a memory device 106. The memory device 106 is responsive to the controller 104. In addition, the controller 104 may include a data interface to a host 102, such as a universal serial bus (USB) interface. In an exemplary embodiment, the host 102 requests data from the controller 104. The controller 104 may access the memory device 106 to acquire the data and provide the data to the host device 102.

The controller 104 may include a device driver, implemented in hardware, software, or a combination thereof. The device driver is configured to access the memory device 106. For example, the device driver may include a block management system configured to access blocks on the memory device 106 and determine the blocks' status as usable or defective block. In an exemplary embodiment, the block manager may allocate a user accessible memory space equal to half of the total number of blocks of the memory device 106. The user accessible data space may include memory blocks from both halves of a memory space, wherein the halves of the memory space are addressed by a significant address bit, such as the most significant address bit. In addition, the block manager may allocate a set of memory blocks not included in the user accessible memory space as resource memory blocks for storing system resources.

In an exemplary embodiment, the memory device 106 is a flash memory device, such as a NAND flash memory device or a NOR flash memory device. In a particular embodiment, the flash memory device is a multi-level cell flash memory device. Alternatively, the flash memory device is a single-level cell flash memory device.

In another exemplary embodiment, FIG. 2 includes an illustration of an embedded system 200. The embedded system 200 includes a processing system 202 coupled to a memory device 210 via an interface 212. The processing system 202 may act to control the memory device 210. The embedded system 200 may, for example, take the form of an MP3 player or another portable electronic device.

Within the processing system 202, a combination of hardware and software forms functional modules, such as an application 208, a resource loader 204, and a device driver 206. When the processing system 202 is to access a system resource or firmware, the resource loader 204 interacts with device driver 206 to acquire the system resource from the memory device 210. For example, the resource loader 204 may determine which resource is to be loaded and interface with the device driver to determine the location of the resource, such as through a look up table or allocation table stored either within the processing system 202 or the memory device 210.

When accessing data, the application 208 interact with the device driver 206 to acquire the data from the memory device 210. In an exemplary embodiment, the device driver 206 accesses an allocation table stored on the processing system 202 or on the memory device 210 to determine the location of the data to be loaded. In an example, the device driver 206 accesses the memory device 210 at the location of the data and acquires the data, passing the data to the application 208.

In an exemplary embodiment, the device driver 206 is configured to determine a set of unusable or defective data blocks on the memory device 210 and to allocate a user accessible memory space including blocks of memory from the memory device 210. In an example, the device driver 206 implements a block manager that allocates usable memory blocks of the memory device 210 to a user accessible memory space. The user accessible memory space includes blocks from at least both halves of the memory device 210 as addressed by a significant address bit, such as the highest significant address bit. In a particular example, the block manager allocates a number of memory blocks to the user accessible memory space that is not more than half of the total number of memory blocks of the memory device 210. For example, the user accessible memory space may include half of the total number of memory blocks of the memory device 210. In addition, the block manager of the device driver 206 may allocate a system resource space that is separate from the user accessible memory space.

When requested, the device driver 206 may indicate that the capacity of the memory device 210 is equal to the user accessible memory space. For example, the device driver 206 may indicate that the memory device capacity is equal to half of the actual number of memory blocks within the memory device 210. For an exemplary 128-megabyte device, the device driver 206 may indicate, for example, to the application 208 that the capacity of the memory device is equal to 64 megabytes, the capacity of the user accessible memory space.

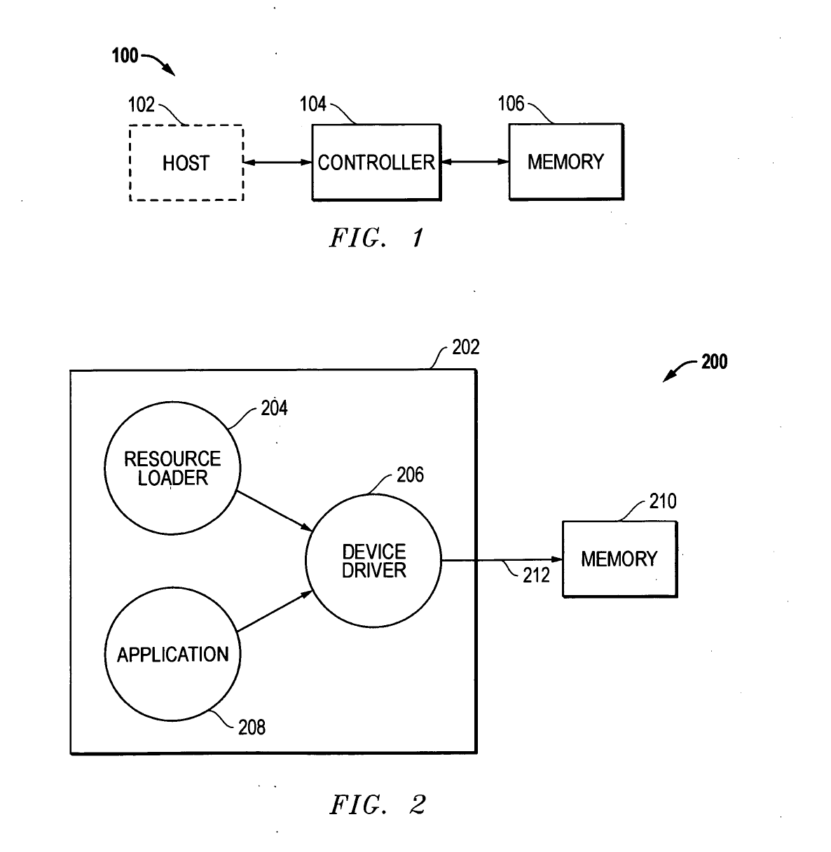

FIGS. 3 and 4 include illustrations of an exemplary memory device. For example, FIG. 3 includes an illustration of a memory device 300 including two halves of an addressable memory, 302 and 304, as addressed by a significant address bit. As illustrated, the memory device 300 includes defective memory blocks 306. In an exemplary embodiment, the number of defective memory blocks 306 exceeds the total number of permissible defective memory blocks permitted by manufacturer specifications. In the illustrated example, the defective memory blocks residing in each half, 302 and 304, of the memory device 300 and the number of defective memory blocks 306 in each half exceeds the maximum number of permissible defective memory blocks for a given half of the memory space. In typical prior art manufacturing, such a memory device 300 is discarded.

FIG. 4 illustrates a memory device 400 including defective memory blocks 406 in both halves (402 and 404) of the memory space. The number of defective memory blocks 406 exceeds the permissible number of defective memory blocks as permitted by manufacturer specifications. In addition, the number of defective memory blocks 406 within each half of the memory space, 402 and 404, exceeds the permissible number of defective memory blocks within half the memory space as addressed by the significant address bit. However, a controller or processing system may be implemented to determine the location of the defective blocks. The controller or processing system may specify a reduced capacity and allocate the reduced capacity of usable blocks to a user accessible memory space. Further, unallocated usable memory blocks may be used to replace blocks with the memory space that failed during operation. In addition, usable memory blocks not allocated to the user accessible memory space may be allocated to a system resource space for storing system resources.

For example, functional memory blocks may be allocated to a user accessible memory space 408. The user accessible memory space 408 include memory blocks residing on both halves (402 and 404) of the addressable memory space as indicated by the highest significant address bit. In a particular embodiment, the usable addressable memory space 408 not more than half of the total number of memory blocks on the memory device 404.

In addition, usable memory blocks may be allocated to a system resource space 410 for storing system resources. In a particular embodiment, the system resource space 410 is separate and distinct from the user accessible memory space 408. As illustrated, the system resource space 410 resides on one half 402 of the addressable memory space. However, the system resource space 410 may include blocks from both halves, 402 and 404, of the addressable memory space.

In addition, the memory device 400 includes usable memory blocks that are unallocated, as illustrated at 412. Such blocks may be used as replacement blocks to supplement blocks that fail within the user accessible memory space 408. In addition, the unallocated blocks 412 may be used to supplement blocks that fail within the system resource space 410.

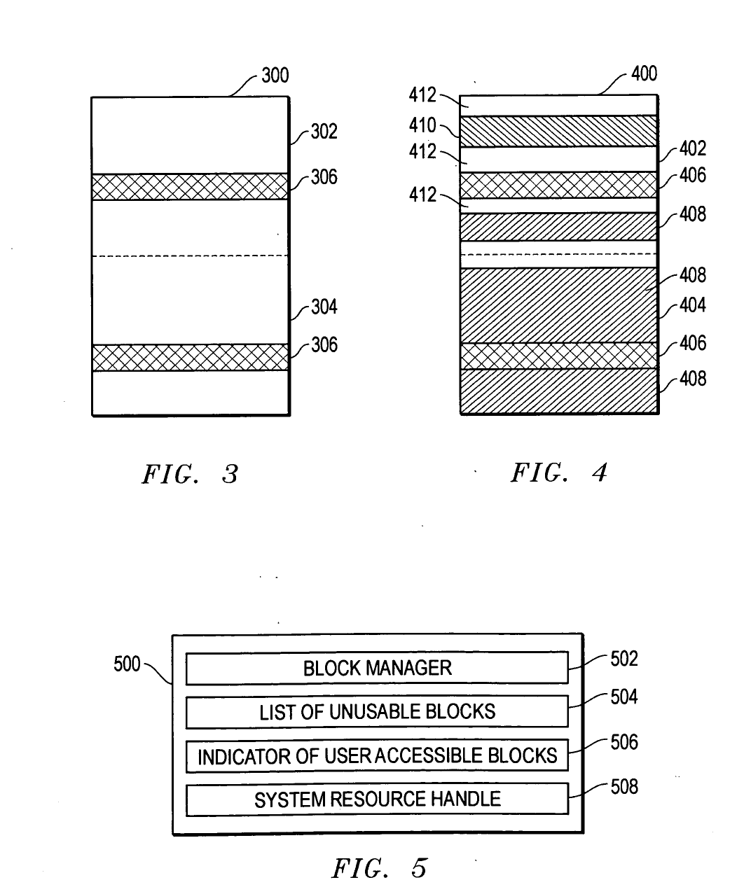

In an exemplary embodiment illustrated in FIG. 5, a device driver or processing system 500 includes a block manager 502. The block manager 502 is configured to determine the number and location of defective data blocks. In an exemplary embodiment, the block manager 502 stores a list of the defective data blocks 504. The block manager 502 may, for example, store the list of defective or unusable data blocks within a controller or processing system 500 or on the memory device. In addition, the block manager 502 is configured to allocate blocks to a user accessible memory space. In a particular embodiment, the user accessible memory space includes half of the total number of memory blocks of the memory device. The block manager 502 may store an indicator 506 of the user accessible memory space, such as an allocation table, a pointer to an allocation table stored on the memory device or an indication of a range of memory blocks that form the user accessible memory space. In general, the block manager 502 allocates memory blocks from both halves of the addressable memory space of the memory device as indicated by the highest significant address bit. In addition, the block manager 502 may determine the location of system resources within the memory device and may store system resource handles 508 a system resource table. For example, a system resource handle 508 be used to access a system resource table located on the memory device and determine a location of a desired system resource.

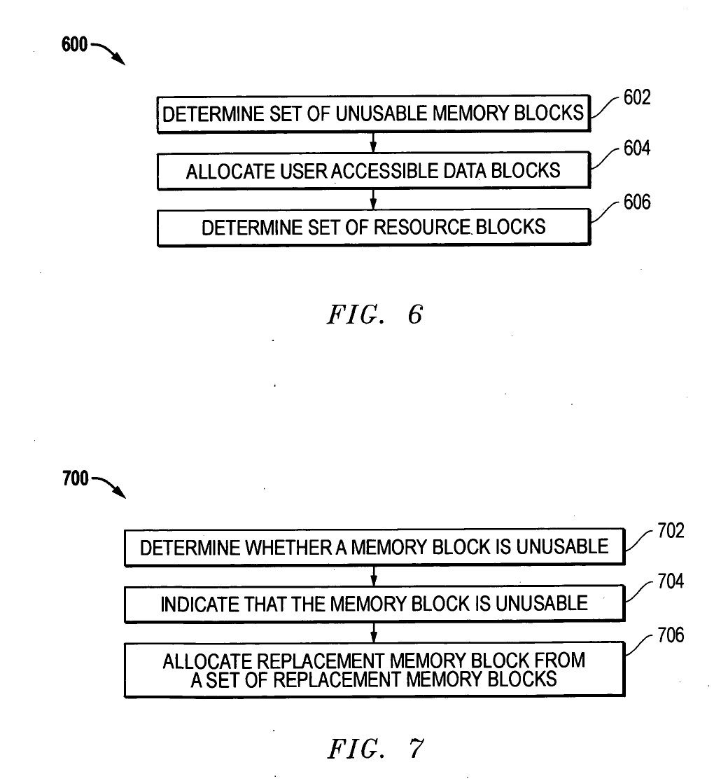

In an exemplary method 600 illustrated in FIG. 6, a block manager or device driver identifies a set of unusable or defective memory blocks, as illustrated at 602. The exemplary method 600 may be implemented during device start up or during device initialization. For example, the device driver may access memory blocks and may check the blocks to locate errors within the blocks. When a block including errors is located, the block manager may store a reference to that block in a list of defective blocks or, alternatively, may include an indicator within metadata associated with the block.

In an exemplary embodiment, the device driver allocates user accessible memory blocks, as illustrated at 604. The user accessible memory blocks form a user accessible memory space that includes memory blocks from both halves of an addressable memory space as indicated by the highest significant address bit. In a particular embodiment, the device driver allocates half of a total number of memory blocks of a memory device to the user accessible memory space. Defective memory blocks are not assigned to the user accessible memory space. When requested, the device driver may indicate a capacity of the user accessible memory space as the capacity of the memory device. In a particular embodiment, the capacity is equal to the capacity of half of the memory device, for example, 64 megabytes of a 128-megabyte memory device.

In addition, the block manager or device driver may determine a set of resource blocks, as illustrated at 606. The set of resource blocks may include a set of system resources or a portion of firmware for an associated electronic device. In a particular embodiment, the set of system resource blocks is separate and distinct from blocks allocated to the user accessible memory space.

In another exemplary method 700 illustrated in FIG. 7, the device driver or block manager periodically reviews the blocks within the memory device, such as the blocks within the user accessible memory space. The device driver or block manager may detect whether a memory block within the memory device is unusable, as illustrated at 702. For example, a memory block within the user accessible memory space may degrade to failure over time. As a result, the block becomes defective or no longer usable. In an exemplary embodiment, the device driver or block manager indicates that the memory block is unusable or defective, as illustrated at 704. For example, the device driver or block manager may add the address of the memory block to a list of defective blocks or may add an indicator within metadata associated with the block that it is defective.

Further, the device driver or block manager may allocate a replacement memory block from the unallocated memory blocks or set of replacement memory blocks, as illustrated at 706. As a result, the block manager or device driver may change the user accessible memory space by, for example, changing an indicator of the addresses of the user accessible memory blocks allocated to the user accessible memory space or changing an allocation table.

Particular embodiments of the above systems and methods permit use of lower cost memory devices. For example, such exemplary methods and systems may permit use of memory devices previously discarded by manufacturers. In addition, such systems and methods may permit extended use of a memory device, in particular, multi-level cell memory devices.

The above-disclosed subject matter is to be considered illustrative, and not restrictive, and the appended claims are intended to cover all such modifications, enhancements, and other embodiments, which fall within the true scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of managing data storage, the method comprising:
detecting an unusable memory block, the unusable memory block in a set of user accessible memory blocks of a memory device, the memory device including the set of user accessible memory blocks, a set of defective memory blocks, and a set of replacement memory blocks, the set of user accessible memory blocks including not more than one half of a total number of memory blocks of the memory device and including memory blocks from both halves of the memory device as addressed by a significant address bit;
indicating that the unusable memory block is a defective memory block; and
allocating a replacement memory block from the set of replacement memory blocks to the set of user accessible memory blocks.

2. The method of claim 1, further comprising allocating the set of user accessible memory blocks.

3. The method of claim 1, further comprising determining the set of defective memory blocks.

4. The method of claim 1, further comprising allocating a set of resource memory blocks for storing system resources, the memory device including the set of user accessible memory blocks, the set of defective memory blocks, the set of replacement memory blocks, and the set of resource memory blocks.

5. The method of claim 1, further comprising reporting a memory capacity based on the set of user accessible memory blocks.

6. The method of claim 1, wherein the memory device is a NAND flash memory device.

7. The method of claim 6, wherein the NAND flash memory device is a multi-level cell solid-state memory device.

8. The method of claim 1, wherein indicating that the unusable memory block is a defective memory block includes writing to metadata associated with the unusable memory block.

9. The method of claim 1, wherein indicating that the unusable memory block is a defective memory block includes adding a reference associated with the unusable memory block to a list of defective memory blocks.

10. The method of claim 1, wherein allocating the replacement memory block includes changing an indicator associated with the set of user accessible memory blocks.

11. A method of managing data storage, the method comprising:
identifying a set of unusable memory blocks of a memory device; and
allocating a user accessible memory space including memory blocks from at least two halves of an addressable memory space as indicated by a significant address bit, the user accessible memory space including not more than half of a total number of memory blocks of the memory device, the memory device including the set of unusable memory blocks, the user accessible memory space, and a set of unallocated memory blocks.

12. The method of claim 11, further comprising:
determining whether a memory block of the user accessible memory space is unusable;
indicating that the memory block is a defective memory block; and
allocating a replacement memory block from the set of unallocated memory blocks to the user accessible memory space.

13. The method of claim 12, wherein indicating that the memory block is defective includes adding a reference to the memory block to a list of defective memory blocks.

14. The method of claim 11, further comprising allocating a resource set of memory blocks separate from the user accessible memory space, the memory device including the set of unusable memory blocks, the resource set of memory blocks, the user accessible memory space, and the set of unallocated memory blocks.

15. The method of claim 11, further comprising communicating a memory capacity of the memory device based on the user accessible memory space.

16. A controller comprising:
logic to identify a user accessible memory space;
a list of unusable memory blocks; and
a block manager configured to access a memory device to allocate the user accessible memory space, the user accessible memory space including memory blocks from at least two halves of an addressable memory space of the memory device based on a significant address bit, the user accessible memory space including not more than half of the total number of memory blocks of the memory device.

17. The controller of claim 16, further comprising an indicator associated with a set of system resource blocks, the memory device including the user accessible memory space, a set of unusable memory blocks, a set of unallocated memory blocks, and the set of system resource blocks.

18. The controller of claim 16, further comprising logic to request access to data stored in the user accessible memory space.

19. The controller of claim 16, further comprising an interface to a host device.

20. The controller of claim 16, wherein the block manager is configured to access a memory device to determine whether a memory block in the user accessible memory space is unusable and to allocate a replacement block to the user accessible memory space from a set of unallocated memory blocks.

21. A device comprising:
a memory device controller; and
a memory device responsive to the controller, the memory device including a user accessible memory space, a set of defective memory blocks, and a set of unallocated memory blocks, the user accessible memory space including memory blocks from at least two halves of the addressable memory space of the memory device based on a significant address bit, the user addressable memory space including not more than half of a total number of memory blocks of the memory device.

22. The device of claim 21, wherein the memory device controller includes an indicator to identify the user accessible memory space.

23. The device of claim 22, wherein the memory device controller includes a list of defective memory blocks.

24. The device of claim 23, wherein the memory device controller includes a block manager configured to access the memory device to allocate the user accessible memory space and to determine the set of defective memory blocks.

25. The device of claim 24, wherein the block manager is configured to access the memory device to determine whether a memory block in the user accessible memory space is unusable and to allocate a replacement block to the user accessible memory space from the set of unallocated memory blocks.

26. The device of claim 21, wherein the memory device controller includes an indicator associated with a set of system resource blocks, the memory device including the user accessible memory space, the set of defective memory blocks, the set of unallocated memory blocks, and the set of system resource blocks.
